(19) United States
(12) Patent Application Publication
(10) Pub. No.: US 2010/0147464 A1
(43) Pub. Date: Jun. 17, 2010

(54) PLASMA TREATMENT APPARATUS

(75) Inventors: Tetsuji Shibata, Osaka (JP); Noriyuki Taguchi, Osaka (JP); Yoshiyuki Nakazono, Osaka (JP)

Correspondence Address: GREENBLUM & BERNSTEIN, P.L.C., 1950 ROLAND CLARKE PLACE, RESTON, VA, 20191, US

(73) Assignee: PANASONIC ELECTRIC WORKS CO., LTD., Osaka (JP)

(21) Appl. No.: 12/527,503

(22) PCT Filed: Feb. 13, 2008
(86) PCT No.: PCT/JP2008/052360

§ 371 Date: Oct. 27, 2009

(30) Foreign Application Priority Data
Feb. 20, 2007 (JP) 2007-039847

(51) Int. Cl. C23F 1/08; C23C 16/00; H05H 1/24

(52) U.S. Cl. 156/345.44; 118/723 E

(57) ABSTRACT

The present invention relates to a plasma treatment apparatus for treating an object to be treated by activating a plasma production gas by an electric discharge, and by blowing this activated plasma production gas onto the object to be treated. A covered electrode is formed by embedding a conductive layer in an insulating substrate made of a ceramic sintered body. The covered electrodes are arranged opposed to each other to form an electric discharge space in a space between the covered electrodes. A power supply is included for causing an electric discharge in the electric discharge space by applying a voltage to the conductive layers. Since no ceramic material is sprayed, it is possible to reduce the costs of the material for the covered electrodes, and to simplify the process for manufacturing the covered electrodes. The ceramic sintered body has a smaller percentage of voids and is thus denser than a coating film formed by spraying a ceramic material, which is less likely to cause dielectric breakdown during an electric discharge.

### TECHNICAL FIELD

The present invention relates to a plasma treatment apparatus used for surface treatment including: the cleaning to remove a foreign substance such as an organic substance existing on a surface of an object to be treated; the peeling and etching of a resist; the improvement in the adhesion properties of an organic film; the reduction of a metal oxide; the forming of a film; pre-plating treatment; pre-coating treatment; pre-painting treatment; and the surface modification of various materials or parts. Particularly, the present invention is preferably applied to the cleaning of the surfaces of electronic parts which are required to be bonded to each other with precision.

### BACKGROUND ART

Heretofore, plasma treatment including the surface modification of an object to be treated is carried out as follows (see Patent Document 1). First, paired electrodes are arranged opposed to each other, and a space between the electrodes is thus formed as an electric discharge space. Subsequently, an electric discharge is caused in the electric discharge space by supplying the electric discharge space with a plasma production gas, and concurrently by applying a voltage to the electrodes. Thereby, plasma is produced. Thereafter, the plasma or its activated species is blown out of the electric discharge space to the object to be treated.

In an apparatus for such plasma treatment, for the purpose of preventing the electrodes from being damaged due to an electric discharge, the surface of each of the electrodes is coated with a coating film which is formed by spraying a ceramic material onto the surface.

In this case, however, there is a problem of higher manufacturing costs because titanium is used as a material of the electrodes due to its advantageous properties that allow titanium to be easily coated by spraying, and because the spraying process is complicated. In addition, coating film formation by spraying generates voids in films at such a high percentage that the films are apt to have defects. Such defects cause a short circuit between the electrodes, and thereby bring about problems of unstable electric discharge and damage on the electrodes.

The present invention has been made with the above-described points taken into consideration. An object of the present invention is to provide a plasma treatment apparatus which is manufacturable at low cost, and capable of preventing an electric discharge from becoming unstable and the electrodes from being damaged.

[Patent Document] JP-A 2004-311116

### DISCLOSURE OF THE INVENTION

For the purpose of solving the above-described problems, a plasma treatment apparatus according to the present invention is a plasma treatment apparatus A for treating an object H to be treated by activating a plasma production gas G by an electric discharge, and then by blowing the activated plasma production gas G onto the object H to be treated. The plasma treatment apparatus comprises: a covered electrode 3 formed by embedding a conductive layer 2 in an insulating substrate 1 made of a ceramic sintered body; an electric discharge space 4 formed between the multiple covered electrodes 3, 3 . . . arranged opposed to each other; and a power supply 5 for causing an electric discharge in the electric discharge space 4 by applying a voltage to the conductive layers 2.

### BRIEF DESCRIPTION OF THE DRAWINGS

FIG. 1 shows an example of an embodiment of the present invention. FIG. 1(a) is a perspective view. FIG. 1(b) is a cross-sectional view. FIG. 1(c) is a bottom plan view.

FIG. 2 is a cross-sectional view showing how to manufacture a covered electrode according to the example.

FIGS. 3(a) and 3(b) are cross-sectional views each showing part of the example.

FIG. 4 is another cross-sectional view showing part of the example.

FIG. 5 shows an example of another embodiment of the present invention. FIG. 5(a) is a perspective view. FIG. 5(b) is a cross-sectional view.

FIG. 6 is a cross-sectional view showing an example of yet another embodiment of the present invention.

FIG. 7 is a cross-sectional view showing an example of still another embodiment of the present invention.

FIG. 8 is a cross-sectional view showing part of the example.

FIG. 9 is schematic views each showing how a lightning surge test was conducted.

### BEST MODES FOR CARRYING OUT THE INVENTION

Descriptions will be hereinbelow provided for the best modes for carrying out the present invention.

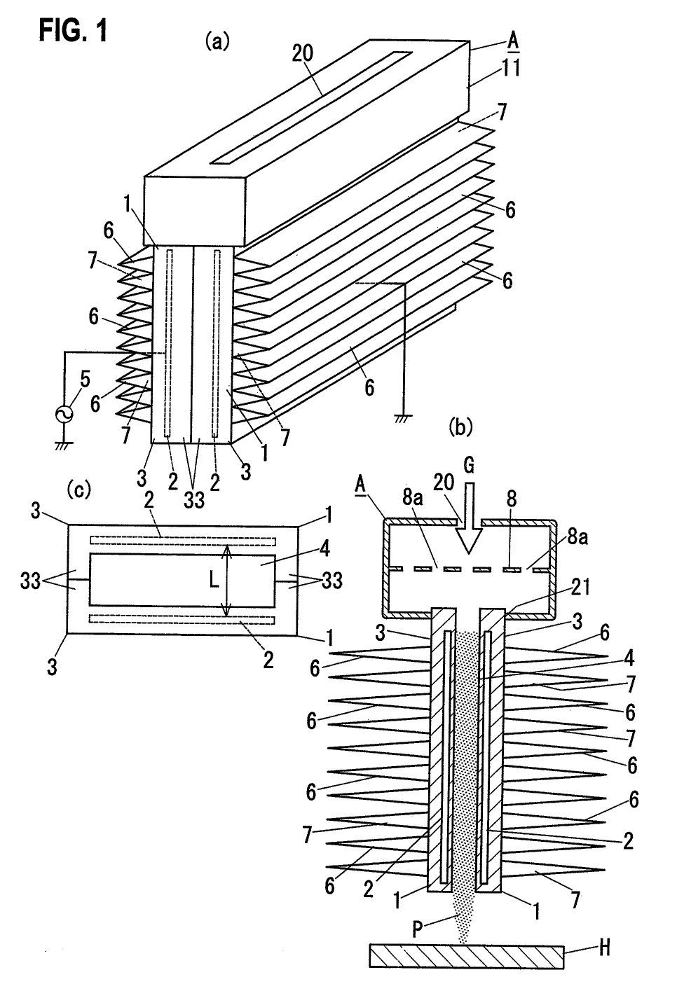

FIGS. 1(a) and 1(b) show an example of a plasma treatment apparatus A of the present invention. This plasma treatment apparatus A is constructed by including multiple covered electrodes 3, a power supply 5, a radiator 6, temperature adjusting means 7, gas homogenizing means 8 and the like.

Each covered electrode 3 is formed by embedding a conductive layer 2 in an insulating substrate (multi-layered substrate) 1 which is almost shaped like a flat plate. The insulating substrate 1 is made of a ceramic sintered body of a refractory insulating material (dielectric material). For instance, the insulating substrate 1 may be made of a high-strength ceramic sintered body with high heat resistance properties, such as alumina, zirconia, mullite or aluminum nitride. However, the material of the insulating substrate 1 is not limited to these. Among these materials, particularly, the insulating substrate 1 is preferably made of alumina or the like which is high in strength and inexpensive. Instead, a high dielectric material such as titania or barium titanate may be used for the insulating substrate 1. Junction parts 33 are respectively provided to two end portions of the insulating substrate 1 so as to project from one side of the insulating substrate 1.

The conductive layer 2 is formed in the shape of a layer in the insulating substrate 1. The conductive layer 2 may be made of a conductive metal material such as copper, tungsten, aluminum, brass, stainless steel or the like. It is desirable that the conductive layer 2 should be made of copper, tungsten or the like in particular.

In this regard, it is desirable to select such materials of the insulating substrate 1 and the conductive layer 2 appropriately so that the difference between the materials in coefficient of linear thermal expansion can be small for the purpose of preventing the insulating substrate 1 and the conductive layer 2 from breaking due to the difference in how much the insulating substrate 1 and the conductive layer 2 are deformed by thermal load during the production of the covered electrode 3 or during plasma treatment.

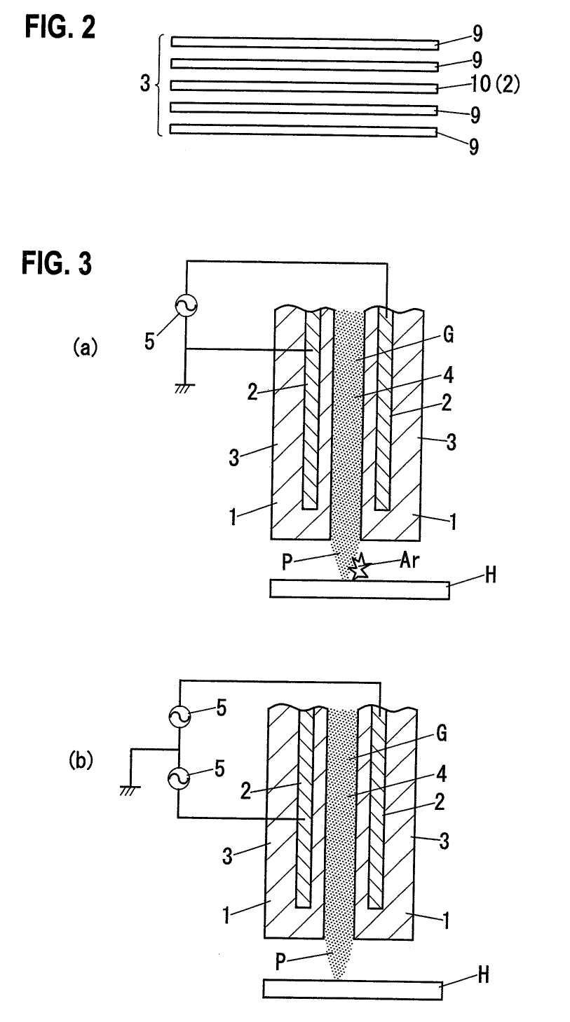

For instance, as shown in FIG. 2, the covered electrode 3 may be formed by use of insulating sheet materials 9 and a conductor 10. Each insulating sheet material 9 can be obtained by mixing a binder and the like with powder of the above-mentioned insulating material such as alumina, further mixing various additives with the resultant mixture as appropriate, and thus shaping this mixed material into a sheet. A sheet of foil, a plate, or the like of the above-mentioned conductive metal such as copper may be used for the conductor 10. Moreover, the conductor 10 may be formed in the shape of a film by printing, plating, or depositing the metal material on a surface of the insulating sheet material 9.

Subsequently, multiple insulating sheet materials 9, 9 . . . are arranged in a stack with the conductor 10 being arranged between the insulating sheet materials 9. Thereafter, the insulating sheet materials 9 thus stacked are formed as an integral unit by sintering. Thereby, the insulating substrate 1 made of the sintered body of the ceramic powder contained in each insulating sheet material 9 is formed, while the conductive layer 2 formed of the conductor 10 is formed in the shape of a layer in this insulating substrate 1. Accordingly, the covered electrode 3 is obtained. Note that conditions for the sintering may be set up depending on what type the ceramic powder is of, how thick the insulating substrate 1 is, and the like whenever deemed necessary.

In the present invention, the insulating substrate 1 may be 0.1 to 10 mm in thickness, whereas the conductive layer 2 may be 0.1 μm to 3 mm in thickness. However, their thicknesses are not limited to these.

Afterward, the multiple (paired) covered electrodes 3, 3 thus formed are arranged opposed to each other in the horizontal direction. Thereby, a space between the opposed surfaces of the respective covered electrodes 3, 3 is formed as an electric discharge space 4. In this respect, it is desirable that an interval L between the conductive layers 2, 2 of the respective covered electrodes 3, 3 opposed as shown in FIG. 1(c) should be set at 0.1 to 5 mm. It is undesirable to set this interval L out of the above-mentioned range. That is because such setting makes an electric discharge unstable, or causes no electric discharge, otherwise makes a larger voltage necessary to cause an electric discharge. The covered electrodes 3, 3 joint together the front ends of the opposed junction parts 33, 33 of the insulating substrates 1, 1. Thereby, the covered electrodes 3, 3 close the opening portions of the respective sides of the electric discharge space 4.

In the present invention, the power supply 5 generates a voltage for activating a plasma production gas G. The waveform of the voltage may be set depending on the necessity. Examples of the waveform include an alternating waveform, a pulse waveform, and a waveform obtained by superimposing these waveforms on each other. In addition, the amplitude and frequency of the voltage applied between the conductive layers 2, 2 may be set appropriately in consideration of the distance between the conductive layers 2, 2, the thickness of each insulating substrate 1 at a portion covering the corresponding conductive layer 2, the material of the insulating substrates 1, the stability of the electric discharge, and the like.

In the present invention, moreover, it is desirable that neutral point grounding should be applied to the conductive layers 2, 2. The neutral point grounding makes it possible to apply a voltage to the two conductive layers 2, 2 while the two conductive layers 2, 2 are floating from the ground. This makes the potential difference between an object H to be treated and an activated plasma production gas (plasma jet) G smaller, thus preventing an arc from being generated. Consequently, it is possible to prevent the object H to be treated from being damaged due to an arc. Specifically, for instance, let us assume a case where, as shown in FIG. 3(a), a potential difference Vp between the conductive layers 2, 2 is set at 13 kV by applying 13 kV to one conductive layer 2 connected to the power supply 5, and concurrently by applying 0 kV to the other conductive layer 2 connected to the ground. In this case, a potential difference of at least several kV is likely to occur between the activated plasma production gas G and the object H to be treated. This potential difference is likely to generate an arc Ar. On the contrary, in a case where the neutral point grounding is applied as shown in FIG. 3(b), a potential difference Vp between the conductive layers 2, 2 can be set at 13 kV by setting an electric potential of one conductive layer 2 at +6.5 kV, and concurrently by setting an electric potential of the other conductive layer 2 at −6.5 kV. In this case, the potential difference between the activated plasma production gas G and the object H to be treated is almost equal to 0 V. In other words, the potential difference between the activated plasma production gas G and the object H to be treated can be made smaller in the case where the neutral point grounding is applied than in the case where no neutral point grounding is applied, although the same potential difference is generated between the conductive layers 2, 2 in both cases. Consequently, the application of the neutral point grounding makes it possible to prevent an arc from being generated from the activated plasma production gas G to the object H to be treated.

In the present invention, a series of multiple radiator fins may be used as the radiator 6. This radiator 6 may be provided in a protruding manner on the external surface of the insulating substrate 1 of each of the covered electrode 3, 3 (that is, on the surface opposed to the electric discharge space 4). This radiator 6 cools the plasma production gas G in the electric discharge space 4 and each covered electrode 3 by air cooling manner. Specifically, although the temperature of the electric discharge space 4 rises high while electricity is discharged therein, this heat is transmitted from the plasma production gas G to the covered electrodes 3, and is thereafter absorbed by the radiator 6. Consequently, the heat is radiated from the radiator 6. This makes it possible to restrain the rise in the temperature of the plasma production gas G, and thus to restrain the rise in the temperature of each insulating substrate 1. Because the radiator 6 restrains the rise in the temperature of each insulating substrate 1, the insulating substrate 1 can be prevented from being thermally deformed, and accordingly can be prevented from being broken such as being cracked. Furthermore, if part of the insulating substrate 1 is excessively heated, an inhomogeneous plasma might be generated because of the higher density of the generated plasma in the heated part, and the like. However, because the temperature rise is restrained in the insulating substrate 1, it is possible to prevent the inhomogeneous plasma from being generated, and accordingly to keep the plasma treatment homogeneous.

It is desirable that the radiator 6 should be made of a material having a high thermal conductivity. The radiator 6 may be made of, for instance, copper, stainless steel, aluminum, aluminum nitride (AlN) or the like. When the radiator 6 is made of an insulating substance such as aluminum nitride, the radiator 6 is less likely to be affected by the high-frequency voltage which is applied between the conductive layers 2, 2. As a result, little electric power applied between the conductive layers 2, 2 is lost. Accordingly, the radiator 6 is capable of discharging electricity effectively. In addition, the radiator 6 is capable of increasing cooling efficiency because of its high thermal conductivity.

It is desirable that each insulating substrate 1 and the radiator 6 should be bonded together by use of a method by which a favorable thermal conductivity is achieved. For example, each insulating substrate 1 and the radiator 6 may be bonded together by use of a thermally conductive grease, a thermally conductive two-sided tape, or an adhesive resin-impregnated bonding material, or may be jointed together by press-fitting the joint surfaces respectively of the insulating substrate 1 and the radiator 6 after the joint surfaces thereof are polished to a mirror finish. Alternatively, it is also desirable that each insulating substrate 1 and the radiator 6 be made as an integrated unit. When each insulating substrate 1 and the radiator 6 are shaped in this manner, heat from the electric discharge space 4 can be efficiently absorbed by the radiator 6. This makes it possible to even the temperature distribution in each insulating substrate 1, and accordingly to stabilize the electric discharge. Instead, a Peltier element may be installed as the radiator 6.

In the present invention, heating means such as an electric heater may be used as the temperature adjusting means 7. The temperature adjusting means 7 adjusts the temperature of each insulating substrate 1 to a temperature which facilitates the emission of secondary electrons. Specifically, secondary electrons are emitted from each insulating substrate 1 when electrons and ions included in the activated plasma gas G work on the insulating substrate 1. The temperature adjusting means 7 adjusts the temperature of the insulating substrate 1 to a temperature which facilitates the emission of the secondary electrons. The higher the temperature of the insulating substrate 1 becomes, the more secondary electrons are emitted therefrom. However, in consideration of possible damage caused in the insulating substrate 1 due to thermal expansion, it is appropriate that the temperature of each insulating substrate 1 should be adjusted so as to be suppressed to around 100° C. Consequently, it is desirable that the temperature of each insulating substrate 1 should be adjusted to 40° C. to 100° C. by the temperature adjusting means 7. By making the temperature of each insulating substrate 1 higher than room temperature as described above, the temperature adjusting means 7 is capable of raising the surface temperature of the insulating substrate 1 above room temperature when the plasma treatment apparatus A starts to be used. This makes more secondary electrons emitted from each insulating substrate 1 than in the case where the surface temperature of the insulating substrate 1 is set at room temperature. The more secondary electrons emitted from each insulating substrate 1 increase the density of the generated plasma, and accordingly make an electric discharge to be started more easily. Thus, the temperature adjusting means 7 enhances the starting performance of the plasma treatment apparatus A. Moreover, the temperature adjusting means 7 can enhance the plasma treatment capability of the plasma treatment apparatus A such as its capability of cleaning the object H to be treated, and its capability of modifying the properties of the object H to be treated.

The temperature adjusting means 7 may be included in the insulating substrate 1, the radiator 6, or the gas homogenizing means 8 to be described later, or may be provided on the external surface thereof. Depending on the necessity, the operation and stop of the temperature adjusting means 7 may be adjusted on the basis of the result of measuring the temperature of each insulating substrate 1 by use of temperature measuring means such as a thermocouple.

In the present invention, a gas reserving chamber (gas reservoir) 11 is provided above the covered electrodes 3, 3. The gas reserving chamber 11 is formed in the shape of a box by use of the same material as that of the radiator 6. The gas reserving chamber 11 has a gas distribution opening 20 formed in its top surface, and has an attachment hole 21 formed in its undersurface. The covered electrodes 3, 3 are attached to the gas reserving chamber 11 by inserting upper portions of the respective covered electrodes 3, 3 into the gas reserving chamber 11 through the attachment hole 21. Thereby, the electric discharge space 4 and the internal space of the gas reserving chamber 11 communicate with each other. The gas homogenizing means 8 is provided in the gas reserving chamber 11. The gas homogenizing means 8 supplies the plasma production gas G to the electric discharge space 4 in a way that the plasma production gas G flows at an almost equal flow rate anywhere in the width direction of the electric discharge space 4 (which is the same as the width direction of each covered electrode 3, and which is a direction orthogonal to the page of FIG. 1(b)). This gas homogenizing means 8 is formed by a punching plate or the like, which is provided with a number of through holes 8a, 8a . . . penetrating the punching plate in the vertical direction. The gas homogenizing means 8 is placed there in such a way as to partition the gas reserving chamber 11 into the upper and lower spaces.

In addition, the plasma treatment apparatus A according to the present invention carries out plasma treatment under atmospheric pressure or under a pressure (100 to 300 kPa) which is close to atmospheric pressure. Specifically, the plasma treatment apparatus A carries out the treatment as follows.

First of all, the plasma production gas G is supplied to the gas reserving chamber 11 by causing the plasma production gas G to flow into the gas reserving chamber 11 through the gas distribution opening 20. As the plasma production gas G, a noble gas, nitrogen, oxygen and air may be used alone or by mixing some of them together. Dry air containing little moisture may be preferably used as the air. Helium, argon, neon, krypton or the like may be used as the noble gas; in consideration of the stability in electric discharge and the economical efficiency, it is desirable to use argon as the noble gas. Furthermore, the noble gas or nitrogen may be used in mixture with a reactant gas such as oxygen and air. Any type of the reactant gas may be selected depending on what type of treatment is to be carried out. For instance, it is desirable to use an oxidative gas such as oxygen, air, CO₂ and N₂O as the reactant gas, in the case of performing cleaning to remove an organic substance existing on a surface of an object H to be treated, removing of a resist, etching of an organic film, cleaning of the surface of an LCD, cleaning of the surface of a glass plate, and the like. In addition, a fluorine-based gas such as CF₄, SF₆, NF₃ may be used as the reactant gas depending on the necessity as well. Use of this fluorine-based gas is effective for etching and asking of silicon, a resist and the like. Moreover, when a metal oxide is reduced, a reducing gas such as hydrogen and ammonia may be used.

The plasma production gas G having been supplied to the gas reserving chamber 11 thereafter flows down in the gas reserving chamber 11, and reaches the upper opening of the electric discharge space 4. While flowing down in the gas reserving chamber 11, the plasma production gas G is distributed among the large number of through holes 8a, 8a . . . to pass the through holes 8a. Accordingly, the gas homogenizing means 8 placed between the gas distribution opening 20 and the upper opening of the electric discharge space 4 works as a component part for dispersing the pressure of the plasma production gas G. For this reason, the gas homogenizing means 8 can supply the electric discharge space 4 with the plasma production gas G in a way that the plasma production gas G flows down in the electric discharge space 4 at the almost equal flow rate anywhere in the width direction of the electric discharge space 4. Consequently, the gas homogenizing means 8 is capable of reducing, in the width direction, the flow distribution of the activated plasma production gas G which is blown out of the lower opening of the electric discharge space 4, thus achieving a homogeneous plasma treatment.

For the purpose of supplying the gas reserving chamber 11 with the plasma production gas G as described above, appropriate gas supplying means (not illustrated) formed of gas cylinders, a gas piping, a mixer and a pressure valve and the like may be provided. For instance, gas cylinders filled with the respective gas components contained in the plasma production gas G are connected to the gas distribution opening 20 of the gas reserving chamber 11 through the gas piping. In this respect, the gas components supplied from the respective gas cylinders are mixed together in a predetermined ratio by the mixer, and the resultant mixed gas is introduced into the electric discharge space 4 at a predetermined pressure which is adjusted by the pressure valve. In addition, it is desirable that the plasma production gas G should be supplied to the electric discharge space 4 at a pressure which enables a predetermined quantity of the plasma production gas G to be supplied to the electric discharge space 4 per unit of time without the plasma production gas G being affected by its pressure loss. Further, it is desirable that the plasma production gas G should be supplied to the electric discharge space 4 in a way that the pressure inside the gas reserving chamber 11 is equal to atmospheric pressure or a pressure which is close to atmospheric pressure (preferably, 100 to 300 kPa).

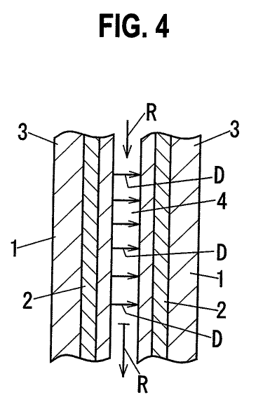

The plasma production gas G having reached the upper opening of the electric discharge space 4 thereafter flows down into the electric discharge space 4 from the upper opening thereof. While flowing down in the electric discharge space 4, the plasma production gas G is activated by an electric discharge which is caused in the electric discharge space 4 by the power supply 5 applying a voltage to the conductive layers 2, 2 of the respective covered electrodes 3, 3 arranged opposed to each other. Specifically, because the power supply 5 applies the voltage to the conductive layers 2, 2, an electric field is generated in the electric discharge space 4. The generation of this electric field causes a gas discharge in the electric discharge space 4 under atmospheric pressure or a pressure which is close to atmospheric pressure. This gas discharge activates the plasma production gas G (or turns the plasma production gas into plasma). Thus, activated species (ions, radicals, and the like) are generated in the electric discharge space 4. At this time, as shown in FIG. 4, an electric line D of force caused in the electric discharge space 4 is almost horizontal from the high-voltage conductive layer 2 toward the low-voltage conductive layer 2, whereas a direction R in which the plasma production gas G is distributed in the electric discharge space 4 is almost perpendicularly downward. In this manner, for the purpose of causing the electric line D of force in a direction which crosses over the distribution direction (the almost perpendicularly downward direction) R of the plasma production gas G in the electric discharge space 4 as described above, the covered electrodes 3, 3 are arranged opposed to each other in a direction (an almost horizontal direction) orthogonal to the distribution direction R of the plasma production gas G, and are then applied with a voltage. Thereby, it is possible to generate an electric discharge, and thus to activate the plasma production gas G.

After the plasma production gas G is activated in the electric charge space 4, this activated plasma production gas G is continuously blown as a jet of plasma P from the lower opening of the electric discharge space 4, and thus is blown onto a part or whole of the surface of the object H to be treated. At this time, the activated plasma production gas G can be blown out widely in the width direction of the covered electrodes 3 (a direction orthogonal to the page of FIG. 1(b)), because the lower opening of the electric discharge space 4 is formed to be long and thin in the width direction thereof. Thus, the activated species contained in the activated plasma production gas G act on the surface of the object H to be treated, thereby enabling treatment of the surface of the object H to be treated such as a cleaning of the object H to be treated. In this respect, in placing the object H to be treated under the lower opening of the electric discharge space 4, the object H to be treated may be conveyed by a conveying apparatus such as a roller and a belt conveyor. At this time, it is also possible to continuously perform plasma treatment on multiple objects H to be treated if the conveying apparatus is arranged to sequentially convey the multiple objects H to be treated under the electric discharge space 4. Furthermore, if held by an articulated robot or the like, the plasma treatment apparatus is capable of treating the surface of the object H to be treated having a complicated solid shape as well. The distance between the lower opening of the electric discharge space 4 and the surface of the object H to be treated may be set at, for instance, 1 to 30 mm, although the distance therebetween may be set up appropriately depending on the flow rate of the plasma production gas G, the type of the plasma production gas G, the object H to be treated, what kind of the surface treatment (plasma treatment) is to be carried out, and the like.

The present invention can be applied to plasma treatment performed on various objects H to be treated. Particularly, the present invention can be applied to surface treatment performed on various glass materials for flat-panel displays, printed wiring boards, various resin films and the like. Examples of the various glass materials for flat-panel displays include glass materials for liquid crystals, glass materials for plasma displays, and glass materials for organic electroluminescence display units. Examples of the various resin films include polyimide films. When surface treatment on such glass materials is performed, a glass material having on its surface an ITO (indium tin oxide) transparent electrode, a TFT (thin film transistor) liquid crystal, a CF (color filter) and the like can be subjected to the surface treatment as well. In addition, when surface treatment is performed on resin films, the surface treatment can be continuously applied to the resin films which are conveyed by use of what is called a roll-to-roll method.

In the present invention, the conductive layer 2 does not need to be made of titanium, and no ceramic material is sprayed. For this reason, the present invention can reduce the costs of the material for the covered electrodes 3, and can simplify the process for manufacturing the covered electrodes 3. The present invention can accordingly manufacture the covered electrodes 3 at low cost. Furthermore, the ceramic sintered body has a percentage of voids smaller than that of the coating film formed by spraying a ceramic material, and is thus denser than the film thus formed. Thus, dielectric breakdown is less likely to occur in each insulating substrate 1 during an electric discharge. Accordingly, the present invention is capable of preventing an unstable electric discharge, and of preventing the conductive layer 2 of each covered electrode 3 from being damaged. Moreover, because of each conductive layer 2 formed in the shape of a layer, the present invention is capable of making each covered electrode 3 thinner, and consequently of reducing the size of the apparatus.

Data on breakdown voltages of a covered electrode 3 used in the present invention and of an electrode (hereinafter referred to as a “conventional electrode”) used in a conventional plasma treatment apparatus will be shown herein. As shown in FIG. 9(a), one obtained by forming a 30 μm-thick tungsten conductor layer 2 at a middle portion in a thickness direction of a 2 mm-thick alumina ceramic sintered body formed as an insulating substrate 1 was used as the covered electrode 3. Consequently, a thickness t of a layer of the insulting substrate 1 which covered the conductive layer 2 was 1 mm. On the other hand, as shown in FIG. 9(b), one obtained by forming an alumina coating film 36 with a thickness t of 1 mm on the surface of a 25 mm-thickness electrode base metal 35 of a titanium plate by spraying was used as the conventional electrode. Subsequently, breakdown voltages respectively of the covered electrode 3 and the conventional electrode were tested by use of an impulse testing machine used for a lightning surge test. Specifically, a breakdown voltage testing electrode 37 was contacted to the surface of each of the insulating substrate 1 and the coating film 36, and the conductive layer 2 and the electrode base metal 35 were grounded. Thereafter, a voltage was applied to each breakdown voltage testing electrode 37 by an impulse power supply 38. As a result, the breakdown voltage of the covered electrode 3 used in the present invention was 20 kV, whereas the breakdown voltage of the conventional electrode was 10 kv. The breakdown voltage performance of the covered electrode 3 was better than that of the conventional electrode (see Table 1).

TABLE 1

| | Thickness of | | Insulator | Breakdown |
|---|---|---|---|---|
| Material | Insulator | Material | Forming Method | Voltage |
| Conventional | 1 mm | Alumina | Spray | 10 kV |
| Electrode | | | | |
| Covered | | | Sinter | 20 kV |
| Electrode 3 | | | (Multilayered- | |
| of Present | | | Substrate | |
| Invention | | | Electrode) | |

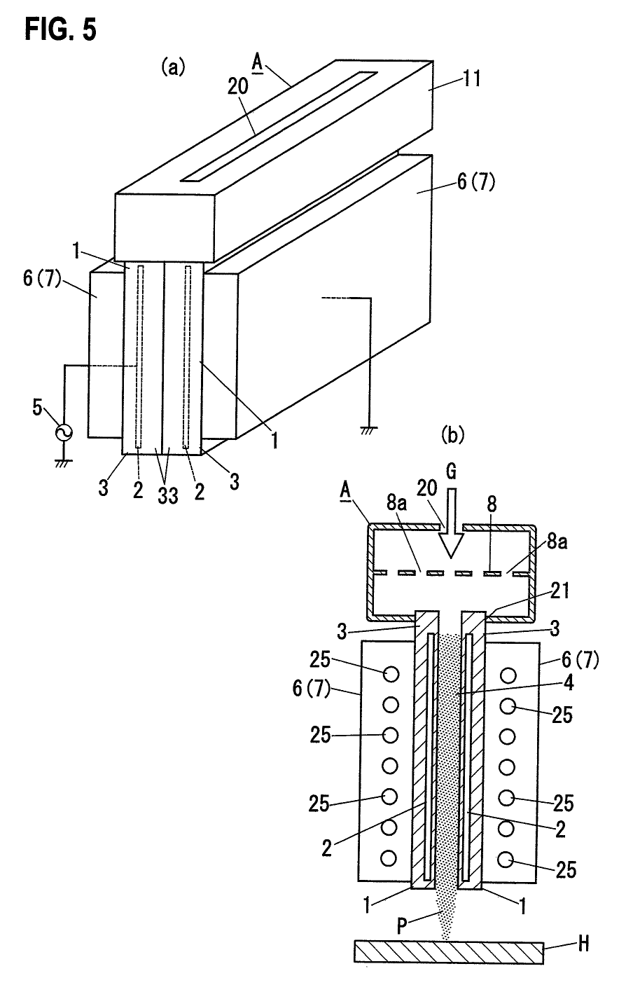

FIGS. 5(a) and 5(b) show another embodiment. In this plasma treatment apparatus A, the radiator 6 is formed with a cooling jacket instead of the series of radiator fins. The rest of the configuration is the same as that of the above-described embodiment. The radiator 6 is formed into the shape of a plate by use of the same material as that of the foregoing embodiment. The radiator 6 includes multiple circulation passages 25 for circulating a coolant such as water by causing the coolant to flow therein. The radiator 6 is placed in close contact with an external surface of each covered electrode 3. The radiator 6 causes the coolant to flow in the circulation passages 25 during an electric discharge, and thus to cool the insulating substrate 1 of each covered electrode 3 by water cooling. Accordingly, the radiator 6 restrains a rise in temperature of each insulating substrate 1. It is desirable that the temperature of the coolant should be set at 50 to 80° C. in consideration of facilitating the effect described above, its ease of handling and energy saving, and the like.

In addition, like the plasma treatment apparatus A described above, the plasma treatment apparatus A may include the temperature adjusting means 7 such as an electric heater. Otherwise, the plasma treatment apparatus A may use the radiator 6 itself as the temperature adjusting means 7. Specifically, by causing the coolant with an adjusted temperature to flow in the circulation passages 25, the radiator 6 (temperature adjusting means 7) is capable of adjusting the temperature of each insulating substrate 1 to a temperature which facilitates the emission of secondary electrons. In this case, it is appropriate that the temperature of each insulating substrate 1 should be adjusted so as to be suppressed to around 100° C. as in the case of the foregoing embodiment. It is desirable to adjust the temperature of each insulating substrate 1 to 40 to 100° C.

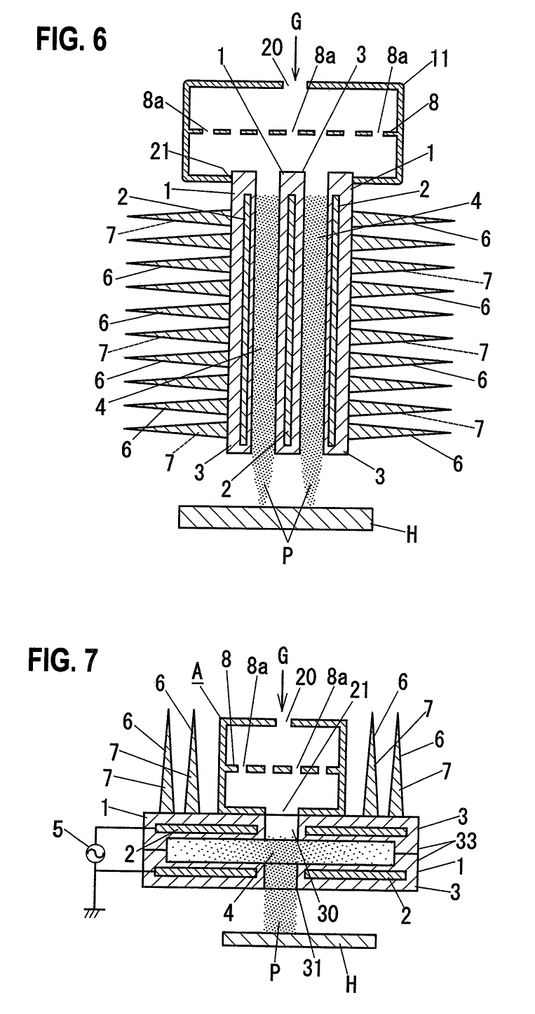

FIG. 6 shows yet another embodiment. This plasma treatment apparatus A is formed by including three covered electrodes 3. The rest of the configuration is the same as that of the foregoing embodiment. The plasma treatment apparatus A of this case is capable of generating more activated plasma production gas G than the plasma treatment apparatus A using the two covered electrodes 3, thus enhancing its plasma treatment capability.

FIG. 7 shows still another embodiment. In this plasma treatment apparatus A, two covered electrodes 3 are arranged opposed to each other in the vertical direction. A gas introduction hole 30 is provided in the upper covered electrode 3 in such a way as to penetrate the upper covered electrode 3 in the vertical direction. A gas lead-out hole 31 is provided in the lower covered electrode 3 in such a way as to penetrate the lower covered electrode 3 in the vertical direction, and to be opposed to the gas introduction hole 30. In addition, a gas reserving chamber 11 similar to the gas reserving chamber 11 described above is placed on the top surface of the upper covered electrode 3. In this case, an attachment hole 21 at the undersurface of the gas reserving chamber 11 and the upper end opening of the gas introduction hole 30 are aligned with each other. Thereby, an electric discharge space 4 between the upper and lower covered electrodes 3, 3 communicates with the internal space of the gas reserving chamber 11. Furthermore, a radiator 6 including a series of radiator fins similar to those described above is provided in a protruding manner on the top surface of the upper covered electrode 3. The rest of the configuration is the same as that of the foregoing embodiment.

Like the plasma treatment apparatus A described above, this plasma treatment apparatus A supplies the plasma production gas G to the gas reserving chamber 11 from a gas distribution opening 20, and causes the plasma production gas G to flow down in the gas reserving chamber 11 while causing the plasma production gas G to pass through holes 8a of gas homogenizing means 8. Thereafter, the plasma treatment apparatus A supplies the resultant plasma production gas G to the electric discharge space 4 through the gas introduction hole 30. Subsequently, the plasma treatment apparatus A activates the plasma production gas G with an electric discharge which is caused in the electric discharge space 4 by a voltage applied between the conductive layers 2, 2 of the respective covered electrodes 3, 3. Thus, the plasma treatment apparatus A blows this activated plasma production gas G through the gas lead-out hole 31, and thus blows the gas onto an object H to be treated which is placed under the gas lead-out hole 31. Thereby, the plasma treatment apparatus A is capable of carrying out plasma treatment.

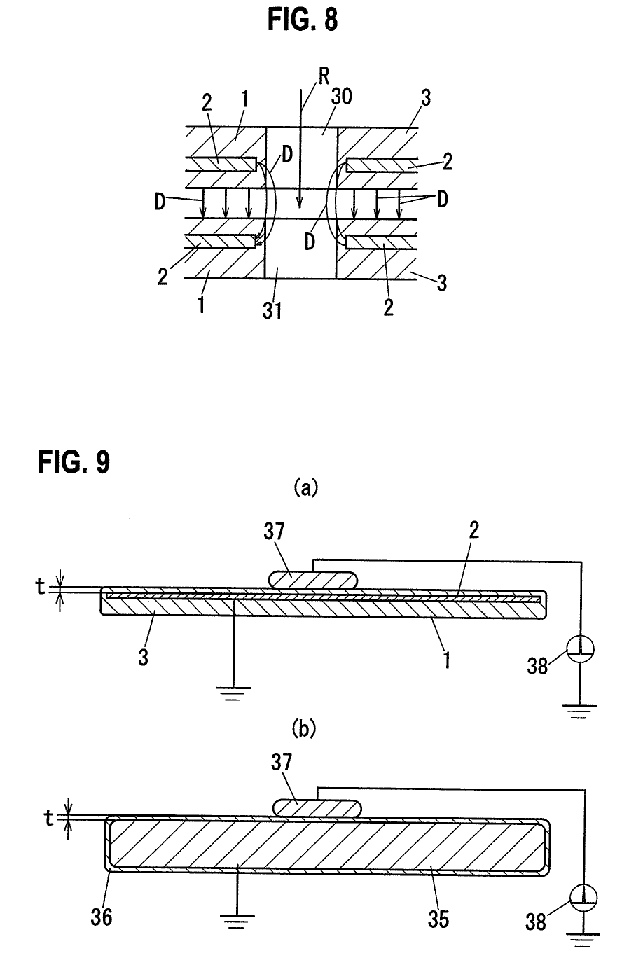

In this plasma treatment apparatus A, as shown in FIG. 8, an electric line D of force caused in the electric discharge space 4 almost perpendicularly extends from the high-voltage conductive layer 2 to the lower-voltage conductive layer 2. The distribution direction R of the plasma production gas G in the electric discharge space 4 extends almost perpendicularly downward as well. For the purpose of causing the electric line D of force in a direction parallel with the distribution direction R of the plasma production gas G in the electric discharge space 4 in this manner, the covered electrodes 3, 3 are arranged opposed to each other in a direction (an almost perpendicular direction) parallel with the distribution direction R of the plasma production gas G, and a voltage is applied to the covered electrodes 3, 3 thus arranged. This makes it possible to cause an electric discharge, and thus to activate the plasma production gas G. In this case, the plasma treatment apparatus A is capable of causing a streamer discharge with high density in a direction substantially parallel with the distribution direction R of the plasma production gas G, and is further capable of making the electric discharge space 4 efficiently activate the plasma production gas G beyond the gas lead-out hole 31. Accordingly, the plasma treatment apparatus A is capable of further enhancing the activation of the plasma production gas G, and thus of carrying out a highly efficient plasma treatment.

### INDUSTRIAL APPLICABILITY

The present invention makes it unnecessary to form the conductive layers 2 of titanium and to spray a ceramic material, when forming the covered electrodes 3. For this reason, the present invention reduces the costs of the material for the covered electrodes 3, and simplifies the process of manufacturing the covered electrodes 3. Consequently, the plasma treatment apparatus can be manufactured at low cost. In addition, the ceramic sintered body has a percentage of voids smaller than that of a coating film formed by spraying a ceramic material, and is thus denser than the coating film thus formed. For this reason, dielectric breakdown is less likely to occur during an electric discharge. Accordingly, the present invention is capable of preventing an unstable electric discharge, and of preventing the conductive layer 2 of each covered electrode 3 from being damaged. Furthermore, each conductive layer 2 is formed in the shape of a layer. Consequently, the present invention is capable of making each covered electrode 3 thinner, and thus of reducing the size of the apparatus.

1. A plasma treatment apparatus for treating an object to be treated by activating a plasma production gas by an electric discharge, and then by blowing the activated plasma production gas onto the object to be treated,
the plasma treatment apparatus comprising:
a covered electrode formed by embedding a conductive layer in an insulating substrate made of a ceramic sintered body;
an electric discharge space formed between a plurality of the covered electrodes arranged opposed to each other; and
a power supply for causing an electric discharge in the electric discharge space by applying a voltage to the conductive layers.

2. The plasma treatment apparatus according to claim 1, wherein
the covered electrodes are arranged so as to generate an electric line of force in a direction crossing a direction in which the plasma production gas flows in the electric discharge space, the electric line of force being generated in the electric discharge space by applying the voltage to the conductive layers.

3. The plasma treatment apparatus according to claim 1, wherein
the covered electrodes are arranged so as to generate an electric line of force in a direction substantially parallel with a direction in which the plasma production gas flows in the electric discharge space, the electric line of force being generated in the electric discharge space by applying the voltage to the conductive layers.

4. The plasma treatment apparatus according to claim 1, wherein
an interval between the neighboring covered electrodes is 0.1 mm to 5 mm.

5. The plasma treatment apparatus according to claim 1, wherein
the ceramic sintered body is an alumina sintered body.

6. The plasma treatment apparatus according to claim 1, further comprising
a radiator provided on an external surface of each insulating substrate.

7. The plasma treatment apparatus according to claim 1, further comprising
temperature adjusting means for adjusting a temperature of each insulating substrate to a temperature which facilitates emission of secondary electrons.

8. The plasma treatment apparatus according to claim 1, further comprising
gas homogenizing means for substantially equalizing a flow rate of the plasma production gas in the electric discharge space.

9. The plasma treatment apparatus according to claim 1, wherein
each covered electrode is formed by integrally forming the insulating substrate made of a plurality of insulating sheet materials, and the conductive layer made of a conductor and interposed between the insulating sheet materials.
